(19) United States
(12) Patent Application Publication
(10) Pub. No.: US 2025/0255149 A1
(43) Pub. Date: Aug. 7, 2025

(54) DISPLAY APPARATUS AND METHOD OF MANUFACTURING THE SAME

(71) Applicant: Samsung Display Co., Ltd., Yongin-Si (KR)

(72) Inventors: Hyunseok Kim, Yongin-si (KR); Shintack Kang, Yongin-si (KR); Youngmin Kim, Yongin-si (KR); Seungjun Yu, Yongin-si (KR)

(21) Appl. No.: 18/928,179

(22) Filed: Oct. 28, 2024

(30) Foreign Application Priority Data
Feb. 2, 2024 (KR) 10-2024-0016914

(51) Int. Cl. H10K 59/80; H10K 59/12

(52) U.S. Cl. CPC H10K 59/873; H10K 59/1201

(57) ABSTRACT

Provided are a display apparatus and a method of manufacturing the display apparatus. The display apparatus includes a substrate comprising a display area and a non-display area outside the display area, a display element layer comprising a light-emitting diode disposed in the display area, an encapsulation layer disposed to cover the display element layer, a pad portion disposed in the non-display area, and an edge dam portion disposed in the non-display area at an outside of the pad portion in the non-display area to be apart from the display area.

### CROSS-REFERENCE TO RELATED APPLICATION

This application is based on and claims priority under 35 U.S.C. § 119 to Korean Patent Application No. 10-2024-0016914, filed on Feb. 2, 2024, in the Korean Intellectual Property Office, the disclosure of which is incorporated by reference herein in its entirety.

### BACKGROUND

### 1. Field

One or more embodiments relate to a display apparatus and a method of manufacturing the same, and more particularly, to a display apparatus and a method of manufacturing the same capable of preventing line damage.

### 2. Description of the Related Art

Recently, electronic devices have been widely used. A variety of electronic devices including mobile electronic devices and stationary electronic devices have been used. Such electronic devices include display apparatuses capable of providing users with visual information such as an image or video to support various functions.

Recently, with the development of various electronic devices such as cellular phones, personal digital assistants (PDAs), computers, large televisions (TVs), etc., various types of display apparatuses which may be implemented in these electronic devices have been developed. For example, display apparatuses that are widely used in the market may include a liquid crystal display apparatus including a backlight unit and an organic light-emitting display apparatus emitting light of a different color for each color area. In addition, a display apparatus including a quantum dot color conversion layer (QD-CCL) has been recently developed. Quantum dots are excited by incident light and emit light having a greater wavelength than the incident light, wherein the incident light is mainly in a low wavelength band. Recently, with the diversified usage of display apparatuses, designs to improve the quality of display apparatuses have been variously introduced.

The background art described above corresponds to technical information possessed by the inventor to derive the disclosure or acquired in the process of deriving the disclosure and may not necessarily correspond to well-known art publicly known before the application of the disclosure.

### SUMMARY

One or more embodiments include a display apparatus and a method of manufacturing the display apparatus capable of preventing line damage in a non-display area.

However, this objective is only an example, and the objective to be solved by the disclosure is not limited thereto.

Additional aspects will be set forth in part in the description which follows and, in part, will be apparent from the description, or may be learned by practice of the presented embodiments of the disclosure.

According to one or more embodiments, a display apparatus includes a substrate including a display area and a non-display area outside the display area, a display element layer including a light-emitting diode and disposed in the display area, an encapsulation layer disposed to cover the display element layer, a pad portion disposed in the non-display area, and an edge dam portion disposed at an outside of the pad portion in the non-display area to be apart from the display area.

The edge dam portion may be disposed along a circumference of the substrate.

The edge dam portion may protrude in an upper direction from the outer end of the substrate.

The edge dam portion may include a resin portion disposed in the non-display area at the outer end of the substrate and protruding in the upper direction and a first partition wall disposed at an inner side of the resin portion toward the display area.

The resin portion may include an acid-resistant material.

The acid-resistant material may include at least one of polyethylene, poly vinyl chloride, and a photoactive compound.

A width of the resin portion may be from about 25 μm or greater to about 75 μm or less.

A height of the first partition wall may be from about 1.5 μm or greater to about 4.5 μm or less.

A thickness of the substrate may be in a range of about 50 μm or greater to about 150 μm or less.

The display apparatus may further include a first dam disposed inside the pad portion in the non-display area, and the edge dam portion may be disposed at an outer side of the first dam.

The display apparatus may further include an overcoat layer disposed above the encapsulation layer and a second dam disposed between the first dam and the pad portion in the non-display.

The pad portion is disposed between the edge dam portion and the second dam portion.

According to one or more embodiments, a method of manufacturing a display apparatus includes preparing a display substrate including a mother substrate and a plurality of layers stacked on the mother substrate, forming a first partition wall and a second partition wall at an outer side of a pad portion, the first partition wall being disposed inside of a cutting line of the display substrate and the second partition wall being disposed outside of the cutting line of the display substrate, forming a resin in a space between the first partition wall and the second partition wall to overlap the cutting line in a plan view, and separating the display substrate along the cutting line.

The method may further include preliminarily cutting the mother substrate by using a laser on the mother substrate along the cutting line before the separating the display substrate.

The separating the display substrate may include etching the mother substrate so that a thickness of the mother substrate is reduced.

An etchant may penetrate through a portion of the mother substrate that is preliminarily cut and cut the display substrate.

The thickness of the mother substrate may be in a range of about 50 μm or greater to about 150 μm or less.

The resin may include an acid-resistant material.

The acid-resistant material may include at least one of polyethylene, poly vinyl chloride, and a photoactive compound.

A width of the resin may be from about 50 μm or greater to about 150 μm or less.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display apparatus according to an embodiment;

FIG. 2 is a schematic cross-sectional view of a display apparatus according to an embodiment;

FIG. 3 illustrates each of optical layers of a functional layer of FIG. 2;

FIG. 4 is an equivalent circuit diagram of a light-emitting diode included in a display apparatus and a sub-pixel circuit electrically connected to the light-emitting diode according to an embodiment;

FIG. 5 is a schematic cross-sectional view of the display apparatus according to an embodiment which is taken along line A-A′ of FIG. 1; and

FIGS. 6, 7, 8, 9 and 10 are schematic views for describing a method of manufacturing a display apparatus, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

While the disclosure is capable of various modifications and alternative forms, embodiments thereof are shown by way of example in the drawings and will herein be described in detail. Effects and characteristics of the disclosure and methods of achieving the same will become apparent by referring to the embodiments described in detail below along with the drawings. However, the disclosure is not limited to the embodiments disclosed hereinafter and may be realized in various forms.

Hereinafter, embodiments will be described in detail by referring to the accompanying drawings, wherein, when describing the accompanying drawings, elements that are the same as or corresponding to each other will be assigned the same reference numerals, repeated descriptions thereof will not be given.

It will be understood that although the terms “first,” “second,” etc. may be used herein to describe various components, these components should not be limited by these terms. These components are only used to distinguish one component from another.

As used herein, the singular expressions “a,” “an,” and “the” are intended to include the plural forms as well, unless the context clearly indicates otherwise.

It will be further understood that the terms “comprises” and/or “comprising” used herein specify the presence of stated features or elements, but do not preclude the presence or addition of one or more other features or elements.

It will be understood that when a layer, region, or element is referred to as being formed “on” another layer, area, or element, it can be directly or indirectly formed on the other layer, region, or element. That is, for example, intervening layers, regions, or elements may be present.

Sizes of elements in the drawings may be exaggerated for convenience of explanation. For example, sizes and thicknesses of the elements in the drawings are randomly indicated for convenience of explanation, and thus, the disclosure is not necessarily limited to the illustrations of the drawings.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

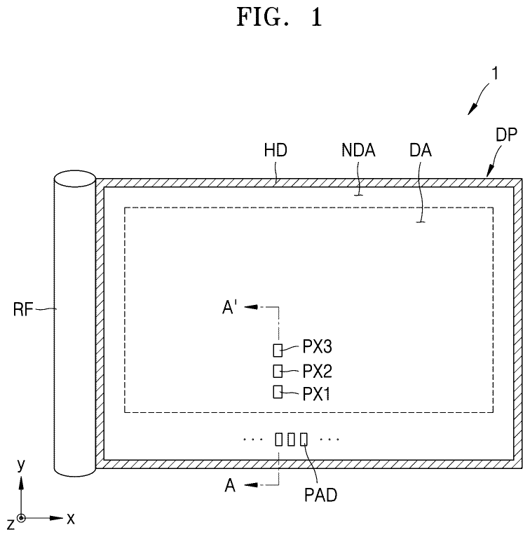

FIG. 1 is a schematic perspective view of a display apparatus 1 according to an embodiment.

Referring to FIG. 1, the display apparatus 1 according to an embodiment may include a rollable display apparatus. In detail, the display apparatus 1 according to an embodiment may include a roll frame RF and a display DP wound in a roll shape in the roll frame RF. That is, FIG. 1 illustrates the display apparatus 1 having the display DP in an unrolled state.

The roll frame RF may include a shaft (not shown) inside thereof. The shaft may be coupled to an end of the display DP, and the display DP may be wound around the shaft. To this end, the display DP may be flexible. Hereinafter, the display DP is to be mainly described.

The display apparatus 1 may include a display area DA displaying an image and a non-display area NDA not displaying an image. The display apparatus 1 may provide an image through an array of a plurality of sub-pixels two-dimensionally arranged in the display area DA on an x-y plane. Each sub-pixel may emit a different color of light, and may be, for example, one of a red sub-pixel, a green sub-pixel, and a blue sub-pixel.

According to an embodiment, the plurality of sub-pixels may include a first sub-pixel PX1, a second sub-pixel PX2, and a third sub-pixel PX3. Hereinafter, for convenience of explanation, it is described that the first sub-pixel PX1 is a red sub-pixel, the second sub-pixel PX2 is a green sub-pixel, and the third sub-pixel PX3 is a blue sub-pixel.

The first sub-pixel PX1, the second sub-pixel PX2, and the third sub-pixel PX3 may be areas to emit red light Lr, green light Lg, and blue light Lb, respectively, and the display apparatus 1 may provide an image by using the light emitted from the sub-pixels.

The non-display area NDA may be an area which may not provide an image and may at least partially surround the display area DA. According to an embodiment, the non-display area NDA may entirely surround the display area DA. A driver or a main voltage line configured to provide electrical signals or power to pixel circuits may be arranged in the non-display area NDA. The non-display area NDA may include a pad PAD which is an area to which an electronic device or a printed circuit board may be electrically connected.

The display area DA may have a polygonal shape including a quadrangular shape as illustrated in FIG. 1. For example, the display area DA may have a rectangular shape having a horizontal length that is greater than a vertical length, a rectangular shape having a horizontal length that is less than a vertical length, or a square shape. According to one embodiment, the display area DA may have a circular shape, an elliptical shape, or a polygonal shape such as a triangular shape or a pentagonal shape. Also, although FIG. 1 illustrates that the display apparatus 1 is a rollable display apparatus that is rollable, the display apparatus 1 may be realized in various forms such as a flexible display apparatus, a foldable display apparatus, or a flat display apparatus. As described below, the rollable display apparatus 1 may have the minimized thickness of a substrate to improve the rolling characteristics.

According to an embodiment, the display apparatus 1 may include an organic light-emitting display apparatus. According to one embodiment, the display apparatus 1 may include an inorganic light-emitting display apparatus or a quantum-dot light-emitting display apparatus. For example, an emission layer of a display element included in the display apparatus 1 may include an organic material, an inorganic material, quantum dots, an organic material and quantum dots, an inorganic material and quantum dots, or an organic material, an inorganic material, and quantum dots. Hereinafter, for convenience of explanation, the case where the display apparatus 1 is an organic light-emitting display apparatus is mainly described in detail.

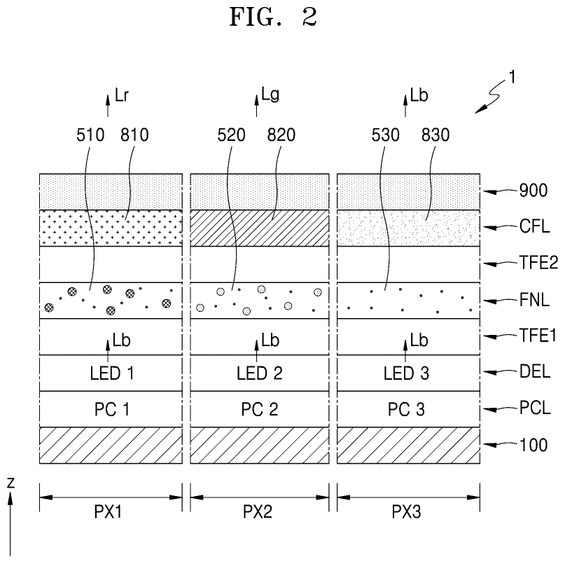

FIG. 2 is a schematic cross-sectional view of the display apparatus 1 according to an embodiment.

Referring to FIG. 2, the display apparatus 1 may include a circuit layer PCL disposed on a substrate 100. The circuit layer PCL may include a first sub-pixel circuit PC1, a second sub-pixel circuit PC2, a third sub-pixel circuit PC3, and insulating layers, and each of the first to third sub-pixel circuits PC1 through PC3 may include a thin-film transistor and/or a capacitor. A display element layer DEL may include a first light-emitting diode LED1, a second light-emitting diode LED2, and a third light-emitting diode LED3, as display elements. The first to third sub-pixel circuits PC1 to PC3 may be electrically connected to the first to third light-emitting diodes LED1 to LED3 of the display element layer DEL, respectively.

The first to third light-emitting diodes LED1 to LED3 may include organic light-emitting diodes including organic materials. According to one embodiment, the first to third light-emitting diodes LED1 to LED3 may include inorganic light-emitting diodes including inorganic materials. The inorganic light-emitting diode may include a PN junction diode including inorganic semiconductor-based materials. When a voltage is applied to the PN junction diode in a normal direction, holes and electrons may inject into the PN junction diode, and energy generated by recombination of the holes and the electrons may convert into light energy to emit light of a predetermined color. The inorganic light-emitting diode described above may have a width that is several to hundreds of micrometers or several to hundreds of nanometers. According to some embodiments, the first to third light-emitting diodes LED1 to LED3 may be light-emitting diodes including quantum dots. As described above, emission layers of the first to third light-emitting diodes LED1 to LED3 may include organic materials, inorganic materials, quantum dots, organic materials and quantum dots, or inorganic materials and quantum dots.

The first to third light-emitting diodes LED1 to LED3 may emit the same color of light. For example, the first to third light-emitting diodes LED1 to LED3 may emit blue light Lb. However, the disclosure is not limited thereto. According to one embodiment, the first to third light-emitting diodes LED1 to LED3 may emit different colors of light. The light (for example, blue light Lb) emitted from the first to third light-emitting diodes LED1 to LED3 may pass through a first encapsulation layer TFE1 disposed on the display element layer DEL and may be transmitted through a functional layer FNL.

The functional layer FNL may include optical layers configured to transmit the light (for example, the blue light Lb) emitted from the display element layer DEL by converting or not converting the color of the light. For example, the functional layer FNL may include quantum-dot layers configured to convert the light (for example, the blue light Lb) emitted from the display element layer DEL into a different color of light or a transmission layer configured to transmit the light (for example, the blue light Lb) emitted from the display element layer DEL without converting the color of the light. The functional layer FNL may include a first quantum-dot layer 510 disposed in an area corresponding to the first sub-pixel PX1, a second quantum-dot layer 520 disposed in an area corresponding to the second sub-pixel PX2, and a transmission layer 530 disposed in an area corresponding to the third sub-pixel PX3. The first quantum-dot layer 510 may convert the blue light Lb into red light Lr, and the second quantum-dot layer 520 may convert the blue light Lb into green light Lg. The transmission layer 530 may transmit the blue light Lb without converting the color of the light.

A color filter CFL may be disposed on the functional layer FNL. A second encapsulation layer TFE2 may be disposed between the functional layer FNL and the color filter CFL. The color filter CFL may include a first color filter 810, a second color filter 820, and a third color filter 830 each of which selectively transmits a specific color of light. According to an embodiment, the first color filter 810 may be a red color filter which transmit red light, the second color filter 820 may be a green color filter which transmit green light, and the third color filter 830 may be a blue color filter which transmit blue light.

The light having the color converted by the functional layer FNL and the light transmitted by the functional layer FNL may have improved color purity by passing through the first to third color filters 810 to 830. Also, the color filter CFL may prevent or minimize the phenomenon that external light (for example, light that is incident toward the display apparatus 1 from the outside of the display apparatus 1) is reflected and becomes visible to a user.

An overcoat layer 900 may be disposed on the color filter CFL. The overcoat layer 900 may include an organic material. For example, the overcoat layer 900 may include a transmissive organic material such as acryl-based resins. The overcoat layer 900 may perform a buffer function with respect to external pressure, etc. and may provide a planarized upper surface.

According to an embodiment, the second encapsulation layer TFE2, and the color filter CFL area sequentially formed on the functional layer FNL on the first encapsulation layer TFE1, the overcoat layer 900 may be directly formed and hardened on the color filter CFL. According to some embodiments, another optical film, for example, an anti-reflection (AR) film, etc., may be disposed on the overcoat layer 900. Also, according to some embodiments, a window (not shown) may further be disposed on the overcoat layer 900.

The display apparatus 1 having the structure described above may include an electronic device capable of displaying a video or a still image such as a television, a billboard, a movie theater screen, a monitor, a tablet personal computer (PC), a notebook computer, etc.

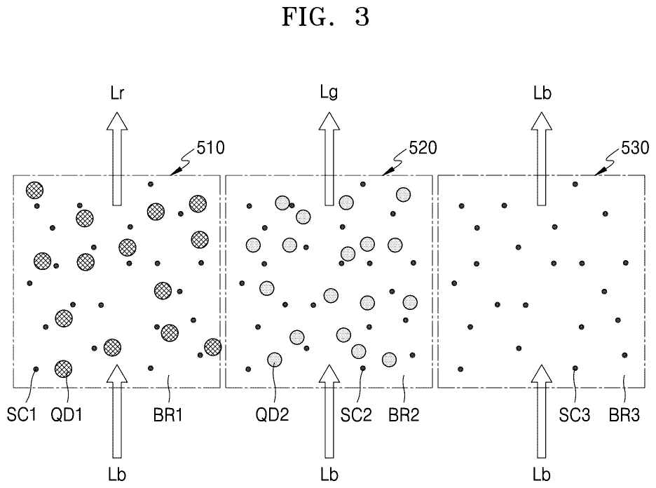

FIG. 3 illustrates each of the optical layers of the functional layer FNL of FIG. 2.

Referring to FIG. 3, the first quantum-dot layer 510 may covert blue light Lb incident into the first quantum-dot layer 510 into red light Lr. As illustrated in FIG. 3, the first quantum-dot layer 510 may include a first photo-sensitive polymer BR1 and first quantum dots QD1 and first scattering particles SC1 which are distributed in the first photo-sensitive polymer BR1.

The first quantum dots QD1 may be excited by the blue light Lb and may emit the red light Lr having a greater wavelength than the blue light Lb in an isotropic fashion. The first photo-sensitive polymer BR1 may include a light-transmissive organic material. The first scattering particles SC1 may scatter the blue light Lb not absorbed by the first quantum dots QD1 and may thus excite more first quantum dots QD1 to improve the color-conversion efficiency. The first scattering particles SC1 may include, for example, titanium oxide TiO₂ or metal particles. The first quantum dots QD1 may be selected from a Groups II-VI compound, a Groups III-V compound, a Groups IV-VI compound, a Group IV element, a Group IV compound, and a combination thereof.

The second quantum-dot layer 520 may convert the incident blue light Lb into green light Lg. As illustrated in FIG. 3, the second quantum-dot layer 520 may include a second photo-sensitive polymer BR2 and second quantum dots QD2 and second scattering particles SC2 which are distributed in the second photo-sensitive polymer BR2.

The second quantum dots QD2 may be excited by the blue light Lb and may emit the green light Lg having a greater wavelength than the blue light Lb in an isotropic fashion. The second photo-sensitive polymer BR2 may include a light-transmissive organic material.

The second scattering particles SC2 may scatter the blue light Lb not absorbed by the second quantum dots QD2 and may thus excite more second quantum dots QD2 to improve the color-conversion efficiency. The second scattering particles SC2 may include, for example, titanium oxide TiO₂ or metal particles. The second quantum dots QD2 may be selected from a Groups II-VI compound, a Groups III-V compound, a Groups IV-VI compound, a Group IV element, a Group IV compound, and a combination thereof.

According to some embodiments, the first quantum dots QD1 may include the same material as the second quantum dots QD2. In this case, the sizes of the second quantum dots QD2 may be smaller than the sizes of the first quantum dots QD1.

The transmission layer 530 may transmit the blue light Lb that is incident into the transmission layer 530 without converting the color of the light. As illustrated in FIG. 3, the transmission layer 530 may include a third photo-sensitive polymer BR3 in which third scattering particles SC3 are distributed. The third photo-sensitive polymer BR3 may include a light-transmissive organic material such as silicon resins, epoxy resins, etc., and may include the same material as the first and second photo-sensitive polymers BR1 and BR2. The third scattering particles SC3 may scatter and emit the blue light Lb and may include the same material as the first and second scattering particles SC1 and SC2.

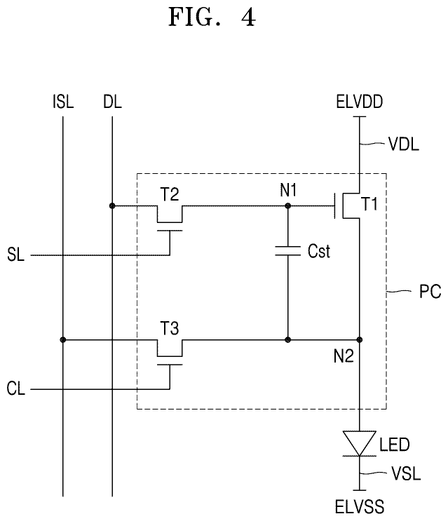

FIG. 4 is an equivalent circuit diagram of a light-emitting diode LED included in a display apparatus and a sub-pixel circuit PC electrically connected to the light-emitting diode LED according to an embodiment. The sub-pixel circuit PC illustrated in FIG. 4 may correspond to each of the first to third sub-pixel circuits PC1 to PC3 described above with reference to FIG. 2, and the light-emitting diode LED of FIG. 4 may correspond to each of the first to third light-emitting diodes LED1 to LED3 described above with reference to FIG. 2.

Referring to FIG. 4, a sub-pixel electrode (for example, an anode) of the light-emitting diode LED may be connected to the sub-pixel circuit PC and an opposite electrode (for example, a cathode) of the light-emitting diode LED may be connected to a common voltage line VSL configured to provide a common voltage ELVSS or an auxiliary line (not shown). The light-emitting diode LED may emit light with a brightness corresponding to the amount of currents supplied from the sub-pixel circuit PC.

The sub-pixel circuit PC may be configured to control the amount of current flowing from a driving voltage ELVDD to the common voltage ELVSS through the light-emitting diode LED in response to a data signal. The sub-pixel circuit PC may include a first thin-film transistor T1, a second thin-film transistor T2, a third thin-film transistor T3, and a storage capacitor Cst.

Each of the first to third thin-film transistors T1 to T3 may include an oxide semiconductor transistor including a oxide semiconductor layer or a silicon semiconductor transistor including polysilicon semiconductor layer. According to a type of the thin-film transistor, a first electrode of the thin-film transistor may be one of a source electrode and a drain electrode, and a second electrode of the thin-film transistor may be the other of the source electrode and the drain electrode.

The first thin-film transistor T1 may be a driving thin-film transistor. A first electrode of the first thin-film transistor T1 may be connected to a driving voltage line VDL configured to supply the driving voltage ELVDD and a second electrode of the first thin-film transistor T1 may be connected to the sub-pixel electrode of the light-emitting diode LED. A gate electrode of the first thin-film transistor T1 may be connected to a first node N1. The first thin-film transistor T1 may be configured to control the amount of currents flowing from the driving voltage line VDL to the common voltage line VSL through the light-emitting diode LED based on a voltage of the first node N1.

The second thin-film transistor T2 may be a switching thin-film transistor. A first electrode of the second thin-film transistor T2 may be connected to a data line DL, and a second electrode of the second thin-film transistor M2 may be connected to the first node N1. A gate electrode of the second thin-film transistor T2 may be connected to a scan line SL. When a scan signal is provided to the second thin-film transistor T2 through the scan line SL, the second thin-film transistor T2 may be turned on and may electrically connect the data line DL with the first node N1.

The third thin-film transistor T3 may be an initialization thin-film transistor and/or a sensing thin-film transistor. A first electrode of the third thin-film transistor T3 may be connected to a second node N2, and a second electrode of the third thin-film transistor M3 may be connected to a sensing line ISL. A gate electrode of the third thin-film transistor T3 may be connected to a control line CL.

The storage capacitor Cst may be connected between the first node N1 and the second node N2. For example, a first capacitor electrode of the storage capacitor Cst may be connected to the gate electrode of the first thin-film transistor T1, and a second capacitor electrode of the storage capacitor Cst may be connected to the sub-pixel electrode of the light-emitting diode LED.

FIG. 4 illustrates that the first to third thin-film transistors T1 to T3 are n-type metal oxide semiconductor (NMOS) transistors. However, the disclosure is not limited thereto. For example, at least one of the first thin-film transistor T1, the second thin-film transistor T2, and the third thin-film transistor T3 may be provided as a p-type metal oxide semiconductor (PMOS) transistor.

FIG. 4 illustrates the three thin-film transistors and one capacitor. However, the disclosure is not limited thereto. The sub-pixel circuit PC may include four or more thin-film transistors and more than one capacitor.

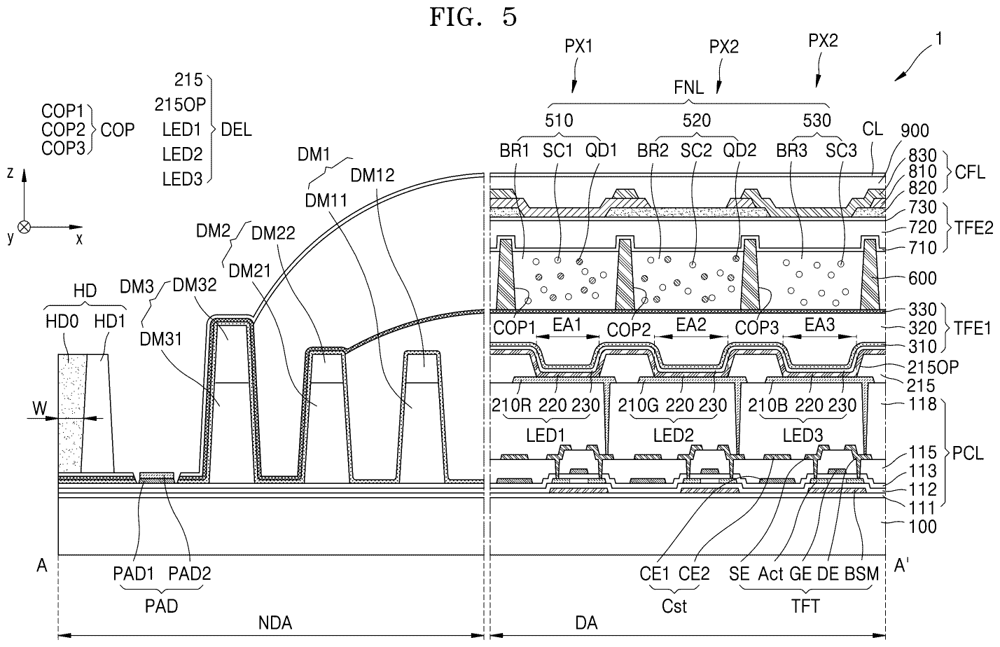

FIG. 5 is a schematic cross-sectional view of the display apparatus 1 according to an embodiment, which is taken along line A-A′ of FIG. 1. Referring to FIG. 5, the display apparatus 1 may include a first sub-pixel PX1, a second sub-pixel PX2, and a third sub-pixel PX3 emitting different colors of light and disposed in the display area DA. For example, the first sub-pixel PX1 may emit red light Lr, the second sub-pixel PX2 may emit green light Lg, and the third sub-pixel PX3 may emit blue light Lb.

The display apparatus 1 may include a substrate 100 and a stacked structure disposed on the substrate 100. The stacked structure including the circuit layer PCL, the display element layer DEL, the functional layer FNL, and the color filter CFL. The display element layer DEL may include first to third light-emitting diodes LED1 to LED3 electrically connected to sub-pixel circuits of the circuit layer PCL. The circuit layer PCL may include the plurality of sub-pixel circuits corresponding to the first to third sub-pixels PX1 to PX3, respectively. The sub-pixel circuits may include a plurality of thin-film transistors TFT and a storage capacitor Cst as described above with reference to FIG. 4. For example, the thin-film transistor TFT may include a driving thin-film transistor (see T1 of FIG. 4).

The substrate 100 may include glass or polymer resins. Here, the polymer resins may include at least one of polyether sulfone, polyarylate, polyether imide, polyethylene naphthalate, polyethylene terephthalate, polyphenylene sulfide, polyimide, polycarbonate, cellulose triacetate, and cellulose acetate propionate. The substrate 100 may include a single-layered or a multi-layered structure including the materials described above. According to an embodiment, the substrate 100 may have a structure of an organic material/an inorganic material/an organic material.

The display area DA and the non-display area NDA described above may be applied to all layers of the display apparatus 1. That is, according to an embodiment, the substrate 100 may include the display area DA and the non-display area NDA.

The circuit layer PCL may be disposed on the substrate 100. FIG. 5 illustrates that the circuit layer PCL may include the thin-film transistor TFT, the storage capacitor Cst, and a first buffer layer 111, a second buffer layer 112, a gate insulating layer 113, an interlayer insulating layer 115, and a planarization layer 118 that are disposed below or/and above components of the thin-film transistor TFT and the storage capacitor Cst.

The first buffer layer 111 and the second buffer layer 112 may reduce or prevent the penetration of impurities, moisture, or foreign materials from below the substrate 100. The first buffer layer 111 and the second buffer layer 112 may include an inorganic insulating material such as silicon nitride (SiNₓ), silicon oxynitride (SiON), and silicon oxide (SiOₓ), and may include a single layer or multiple layers including the inorganic insulating materials described above.

A bias electrode BSM may be disposed between the first buffer layer 111 and the second buffer layer 112 to correspond to the thin-film transistor TFT. According to an embodiment, a voltage may be applied to the bias electrode BSM. Also, the bias electrode BSM may prevent external light from reaching a semiconductor layer Act. Thus, the characteristics of the thin-film transistor TFT may be stabilized. According to some embodiments, the bias electrode BSM may be omitted.

The semiconductor layer Act may be disposed on the second buffer layer 112. The semiconductor layer Act may include amorphous silicon or polysilicon. According to one embodiment, the semiconductor layer Act may include oxide of at least one material selected from the group consisting of In, Ga, Sn, Zr, V, Hf, Cd, Ge, Cr, Ti, Al, Cs, Ce, and Zn. According to some embodiments, the semiconductor layer Act may include a Zn oxide-based material such as Zn oxide, In—Zn oxide, Ga—In—Zn oxide, etc. According to some embodiments, the second semiconductor layer Act may include a semiconductor including In—Ga—Zn—O (IGZO), In—Sn—Zn—O (ITZO), or In—Ga—Sn—Zn—O (IGTZO) in which a metal such as In, Ga, or Sn is included in ZnO. The semiconductor layer Act may include a channel area and a source area and a drain area arranged at both sides of the channel area, respectively. A gate electrode GE may overlap the channel area of the semiconductor layer Act.

The gate electrode GE may include a low-resistance metal material. The gate electrode GE may include a conductive material such as Mo, Al, Cu, Ti, etc. and may include a single layer or multilayers including the materials described above.

The gate insulating layer 113 may be disposed between the semiconductor layer Act and the gate electrode GE. The gate insulating layer 113 may include an inorganic insulating material such as SiOₓ, SiNₓ, SiON, aluminum oxide, titanium oxide, tantalum oxide, hafnium oxide, or zinc oxide.

A first electrode CE1 of the storage capacitor Cst may be disposed on the same layer as the gate electrode GE. The first electrode CE1 may include the same material as the gate electrode GE. FIG. 5 illustrates that the gate electrode GE of the thin-film transistor TFT is separately disposed from the first electrode CE1 of the storage capacitor Cst. However, according to one embodiment, the storage capacitor Cst may overlap the thin-film transistor TFT. In this case, the gate electrode GE of the thin-film transistor TFT may function as the first electrode CE1 of the storage capacitor Cst.

The interlayer insulating layer 115 may be provided to cover the gate electrode GE. The interlayer insulating layer 115 may include an inorganic insulating material such as SiOₓ, SiNₓ, SiON, aluminum oxide, titanium oxide, tantalum oxide, hafnium oxide, or zinc oxide.

A second electrode CE2 of the storage capacitor Cst, a source electrode SE, and a drain electrode DE may be disposed above the interlayer insulating layer 115.

The second electrode CE2 of the storage capacitor Cst, the source electrode SE, and the drain electrode DE may include a conductive material including Mo, Al, Cu, Ti, etc. and may include multiple layers or a single layer including the materials described above. For example, the second electrode CE2 of the storage capacitor Cst, the source electrode SE, and the drain electrode DE may have a multi-layered structure of Ti/Al/Ti. The source electrode SE and the drain electrode DE may be in contact with the source area or the drain area of the semiconductor layer Act through a contact hole.

The second electrode CE2 of the storage capacitor Cst may overlap the first electrode CE1 of the storage capacitor Cst with the interlayer insulating layer 115 disposed therebetween to form the storage capacitor Cst. In this case, the interlayer insulating layer 115 may function as a dielectric layer of the storage capacitor Cst.

The planarization layer 118 may be disposed to cover the second electrode CE2 of the storage capacitor Cst, the source electrode SE, and the drain electrode DE. The planarization layer 118 may include a single layer or layers including an organic material and may provide a flat upper surface. The planarization layer 118 may include a general-purpose polymer such as benzocyclobutene (BCB), polyimide, hexamethyldisiloxane (HMDSO), polymethylmethacrylate (PMMA), or polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and a blend thereof.

The display element layer DEL may be disposed on the circuit layer PCL having the structure described above. The display element layer DEL may include the first light-emitting diode LED1, the second light-emitting diode LED2, and the third light-emitting diode LED3 as display elements. The first light-emitting diode LED1, the second light-emitting diode LED2, and the third light-emitting diode LED3 may include a first sub-pixel electrode 210R, a second sub-pixel electrode 210G, and a third sub-pixel electrode 210B, respectively. According to an embodiment, the first light-emitting diode LED1, the second light-emitting diode LED2, and the third light-emitting diode LED3 may commonly include an emission layer 220 and an opposite electrode 230.

The first sub-pixel electrode 210R, the second sub-pixel electrode 210G, and the third sub-pixel electrode 210B may include (semi) transmissive electrodes or reflective electrodes. According to some embodiments, the first sub-pixel electrode 210R, the second sub-pixel electrode 210G, and the third sub-pixel electrode 210B may include conductive oxide such as indium tin oxide (ITO), indium zinc oxide (IZO), zinc oxide (ZnO), indium oxide (In2O3), indium gallium oxide (IGO), or aluminum zinc oxide (AZO). According to an embodiment, the first sub-pixel electrode 210R, the second sub-pixel electrode 210G, and the third sub-pixel electrode 210B may include reflective layers including Ag, Mg, Al, Pt, Pd, Au, Ni, Nd, Ir, Cr, or a compound thereof. The first sub-pixel electrode 210R, the second sub-pixel electrode 210G, and the third sub-pixel electrode 210B may further include layers including ITO, IZO, ZnO, or In₂O₃ disposed above/below the reflective layers described above. For example, the first sub-pixel electrode 210R, the second sub-pixel electrode 210G, and the third sub-pixel electrode 210B may include ITO/Ag/ITO.

A first bank layer 215 may be disposed on the planarization layer 118. The first bank layer 215 may include an opening 215OP exposing a central portion of each of the first sub-pixel electrode 210R, the second sub-pixel electrode 210G, and the third sub-pixel electrode 210B. The first bank layer 215 may cover an edge of each of the first sub-pixel electrode 210R, the second sub-pixel electrode 210G, and the third sub-pixel electrode 210B. The first bank layer 215 may increase distances between the edges of the first sub-pixel electrode 210R, the second sub-pixel electrode 210G, and the third sub-pixel electrode 210R and the opposite electrode 230 disposed above the first sub-pixel electrode 210R, the second sub-pixel electrode 210G, and the third sub-pixel electrode 210B and may thus prevent the occurrence of arc, etc. at the edges of the first sub-pixel electrode 210R, the second sub-pixel electrode 210G, and the third sub-pixel electrode 210B.

The first bank layer 215 may include at least one organic insulating material selected from the group consisting of polyimide, polyamide, acryl resins, BCB, and phenol resins.

The emission layer 220 of each of the first light-emitting diode LED1, the second light-emitting diode LED2, and the third light-emitting diode LED3 may include an organic material including a fluorescent or a phosphorescent material emitting red, green, blue, or white light. The emission layer 220 may include a low molecular-weight organic material or a high molecular-weight organic material. Also, a functional layer such as a hole transport layer (HTL), a hole injection layer (HIL), an electron transport layer (ETL), and an electron injection layer (EIL) may be further selectively disposed below and above the emission layer 220. The emission layer 220 may be integrally formed on the first sub-pixel electrode 210R, the second sub-pixel electrode 210G, and the third sub-pixel electrode 210B as illustrated in FIG. 5. However, the disclosure is not limited thereto. According to some embodiments, the emission layer 220 may include layers patterned to correspond to the first sub-pixel electrode 210R, the second sub-pixel electrode 210G, and the third sub-pixel electrode 210B, respectively. The emission layer 220 may be a first-color emission layer. The first-color emission layer may emit light of a first wavelength band, for example, blue light. According to an embodiment, the emission layer 220 may emit light of the wavelength of 450 nm to 495 nm. The emission layer 220 disposed in the first subpixel PX1, the second subpixel PX2, and the third subpixel PX3 may emit light of different wavelengths.

The opposite electrode 230 may be disposed on the emission layer 220 and may be arranged on the first sub-pixel electrode 210R, the second sub-pixel electrode 210G, and the third sub-pixel electrode 210B. The opposite electrode 230 may be integrally formed throughout the first sub-pixel electrode 210R, the second sub-pixel electrode 210G, and the third sub-pixel electrode 210B. According to an embodiment, the opposite electrode 230 may include a conductive material having a low work function. For example, the opposite electrode 230 may include a (semi) transparent layer including Ag, Mg, Al, Pt, Pd, Au, Ni, Nd, Ir, Cr, Li, Ca, or an alloy thereof. The opposite electrode 230 may further include a layer such as ITO, IZO, ZnO, or In₂O₃ on the (semi-) transparent layer including the material described above.

The first to third sub-pixels PX1 to PX3 may include first to third emission areas EA1 to EA3, respectively. The first to third emission areas EA1 to EA3 may be areas through which the light generated from the first light-emitting diode LED1, the light generated from the second light-emitting diode LED2, and the light generated from the third light-emitting diode LED3 are emitted to the outside. The first emission area EA1 may be defined as a portion of the first sub-pixel electrode 210R exposed by the opening 215OP of the first bank layer 215. The second emission area EA2 may be defined as a portion of the second sub-pixel electrode 210G exposed by the opening 215OP of the first bank layer 215. The third emission area EA3 may be defined as a portion of the third sub-pixel electrode 210B exposed by the opening 215OP of the first bank layer 215. In other words, each of the first emission area EA1, the second emission area EA2, and the third emission area EA3 may be defined by the opening 215OP of the first bank layer 215.

The first emission area EA1, the second emission area EA2, and the third emission area EA3 may be spaced apart from one another. An area of the display area DA, the area excluding the first emission area EA1, the second emission area EA2, and the third emission area EA3, may be a non-emission area. The first emission area EA1, the second emission area EA2, and the third emission area EA3 may be separated by the non-emission area.

A spacer (not shown) for preventing mask imprinting may further be provided on the first bank layer 215. According to an embodiment, the spacer may be integrally formed with the first bank layer 215. For example, the spacer and the first bank layer 215 may be simultaneously formed by the same process using a half-tone mask process.

The first encapsulation layer TFE1 may be disposed to cover the display element layer DEL. The first light-emitting diode LED1, the second light-emitting diode LED2, and the third light-emitting diode LED3 may be easily damaged by moisture or oxygen introduced from the outside. The first encapsulation layer TFE1 may cover and protect the first to third light-emitting diodes LED1 to LED3. The first encapsulation layer TFE1 may cover the display area DA and may extend to the outside of the display area DA, for example, to the non-display area NDA. The first encapsulation layer TFE1 may include at least one organic encapsulation layer and at least one inorganic encapsulation layer. For example, the first encapsulation layer TFE1 may include a first inorganic encapsulation layer 310, a first organic encapsulation layer 320, and a second inorganic encapsulation layer 330 that are sequentially stacked.

The first inorganic encapsulation layer 310 and the second inorganic encapsulation layer 330 may include at least one inorganic material from among aluminum oxide, titanium oxide, tantalum oxide, hafnium oxide, ZnO, SiOₓ, SiNₓ, and SiON. The first organic encapsulation layer 320 may include a polymer-based material. The polymer-based material may include acryl-based resins, epoxy-based resins, polyimide, polyethylene, etc. According to an embodiment, the first organic encapsulation layer 320 may include acrylate. The first organic encapsulation layer 320 may be formed by curing a monomer or by being coated with a polymer.

The first encapsulation layer TFE1 may include the multi-layered structure described above, and thus, even when cracks occur in the first encapsulation layer TFE1, the cracks may not be spread between the first inorganic encapsulation layer 310 and the first organic encapsulation layer 320 or between the first organic encapsulation layer 320 and the second inorganic encapsulation layer 330. A path through which external moisture or oxygen penetrates into the display area DA may be prevented or minimized by the first encapsulation layer TFE1.

According to some embodiments, other layers such as a capping layer, etc. may further be disposed between the first inorganic encapsulation layer 310 and the opposite electrode 230.

A second bank layer 600 may be disposed on the first encapsulation layer FE1, for example, on the second inorganic encapsulation layer 330. The second bank layer 600 may include an organic material or an inorganic material. For example, the second bank layer 600 may include an inorganic material such as SiOₓ, SiNₓ, and/or silicon oxynitride. The second bank layer 600 may include a light-blocking material to function as a light-blocking layer. The light-blocking material may include, for example, at least one of black pigments, black dyes, black particles, and metal articles.

Openings COP may be defined in the second bank layer 600. A first opening COP1 of the second bank layer 600 may be disposed in an area correspond to the opening 215OP of the first bank layer 215 exposing the first sub-pixel electrode 210R, a second opening COP2 of the second bank layer 600 may be disposed in an area correspond to the opening 215OP of the first bank layer 215 exposing the second sub-pixel electrode 210G, and a third opening COP3 of the second bank layer 600 may be disposed in an area correspond to the opening 215OP of the first bank layer 215 exposing the third sub-pixel electrode 210B. That is, in a direction (a z-axis direction) perpendicular to the substrate 100, the first opening COP1 of the second bank layer 600 may be disposed in an area corresponding to the opening 215OP of the first bank layer 215 exposing the first sub-pixel electrode 210R, the second opening COP2 of the second bank layer 600 may be disposed in an area corresponding to the opening 215OP of the first bank layer 215 exposing the second sub-pixel electrode 210G, and the third opening COP3 of the second bank layer 600 may be disposed in an area corresponding to the opening 215OP of the first bank layer 215 exposing the third sub-pixel electrode 210B. Partition walls may be arranged between the first opening COP1, the second opening COP2, and the third opening COP3 of the second bank layer 600.

The functional layer FNL may fill the openings COP of the second bank layer 600. According to an embodiment, the functional layer FNL may include at least one of quantum dots and scattering particles. The functional layer FNL may include a first quantum-dot layer 510, a second quantum-dot layer 520, and a transmission layer 530.

The first quantum-dot layer 510 may fill the first opening COP1 of the second bank layer 600. The first quantum-dot layer 510 may be disposed in the first emission area EA1. The first sub-pixel PX1 may include the first light-emitting diode LED1 and the first quantum-dot layer 510.

The first quantum-dot layer 510 may convert light of a first wavelength band generated from the emission layer 220 on the first sub-pixel electrode 210R into light of a second wavelength band. The first quantum-dot layer 510 may convert blue light into red light. For example, when light of the wavelength of about 450 nm to about 495 nm is generated in the emission layer 220 on the first sub-pixel electrode 210R, the first quantum-dot layer 510 may convert the light of the wavelength of about 450 nm to about 495 nm into light of the wavelength of about 630 nm to about 780 nm. Thus, the first sub-pixel PX1 may emit the light of the wavelength of about 630 nm to about 780 nm to the outside.

The first quantum-dot layer 510 may include a first photo-sensitive polymer BR1 and first quantum dots QD1 and first scattering particles SC1 which are distributed in the first photo-sensitive polymer BR1.

The second quantum-dot layer 520 may fill the second opening COP2 of the second bank layer 600. The second quantum-dot layer 520 may be disposed in the second emission area EA2. The second sub-pixel PX2 may include the second light-emitting diode LED2 and the second quantum-dot layer 520.

The second quantum-dot layer 520 may convert the light of the first wavelength band generated from the emission layer 220 on the second sub-pixel electrode 210G into light of a third wavelength band. The second quantum-dot layer 520 may convert the blue light into green light. For example, when the light of the wavelength of about 450 nm to about 495 nm is generated in the emission layer 220 on the second sub-pixel electrode 210G, the second quantum-dot layer 520 may convert the light of the wavelength of about 450 nm to about 495 nm into light of the wavelength of about 495 nm to about 570 nm. Thus, the second sub-pixel PX2 may emit the light of the wavelength of about 495 nm to about 570 nm to the outside.

The second quantum-dot layer 520 may include a second photo-sensitive polymer BR2 and second quantum dots QD2 and second scattering particles SC2 which are distributed in the second photo-sensitive polymer BR2.

The transmission layer 530 may fill the third opening COP3 of the second bank layer 600. The transmission layer 530 may be disposed in the third emission area EA3. The third sub-pixel PX3 may include the third light-emitting diode LED3 and the transmission layer 530.

The transmission layer 530 may emit light generated from the emission layer 220 on the third sub-pixel electrode 210B to the outside without converting the wavelength of the light. The transmission layer 530 may transmit the blue light without converting the wavelength of the light. For example, when the light of the wavelength of about 450 nm to about 495 nm is generated in the emission layer 220 on the third sub-pixel electrode 210B, the transmission layer 530 may emit the light to the outside without converting the wavelength of the light.

The transmission layer 530 may include a third photosensitive polymer BR3 in which third scattering particles SC3 are distributed. According to an embodiment, the transmission layer 530 may not include quantum dots.

At least one of the first quantum dots QD1 and the second quantum dots QD2 may include a semiconductor material such as CdS, CdTe, ZnS, InP, or the like. The sizes of the quantum dots may be several nanometers and, according to the sizes of the quantum dots, the wavelength of the light after conversion may vary.

According to an embodiment, the quantum dots may include cores and shells. The cores of the quantum dots may be selected from a Groups II-VI compound, a Groups III-V compound, a Groups IV-VI compound, a Group IV element, a Group IV compound, and a combination thereof.

The Groups II-VI compound may be selected from the group consisting of: a two-element compound selected from the group consisting of CdSe, CdTe, ZnS, ZnSe, ZnTe, ZnO, HgS, HgSe, HgTe, MgSe, MgS, and a compound thereof; a three-element compound selected from the group consisting of AgInS, CulnS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a compound thereof; and a four-element compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a compound thereof.

The Groups III-IV compound may be selected from the group consisting of: a two-element compound selected from the group consisting of GaN, GaP, GaAs, GaSb, AlN, AIP, AlAs, AlSb, InN, InP, InAs, InSb, and a compound thereof; a three-element compound selected from the group consisting of GaNP, GaNAs, GaNSb, GaPAs, GaPSb, AlNP, AlNAs, AlNSb, AlPAs, AlPSb, InGaP, InNP, InNAs, InNSb, InPAs, InPSb, GaAINP, and a compound thereof; and a four-element compound selected from the group consisting of GaAINAs, GaAINSb, GaAlPAs, GaAlPSb, GaInNP, GalnNAs, GalnNSb, GalnPAs, GaInPSb, InAINP, InAINAs, InAINSb, InAlPAs, InAlPSb, and a compound thereof.

The Groups IV-VI compound may be selected from the group consisting of: a two-element compound selected from the group consisting of SnS, SnSe, SnTe, PbS, PbSe, PbTe, and a compound thereof; a three-element compound selected from the group consisting of SnSeS, SnSeTe, SnSTe, PbSeS, PbSeTe, PbSTe, SnPbS, SnPbSe, SnPbTe, and a compound thereof; and a four-element compound selected from the group consisting of SnPbSSe, SnPbSeTe, SnPbSTe, and a compound thereof. The Group IV element may be selected from the group consisting of Si, Ge, and a compound thereof. The Group IV compound may be a two-element compound selected from the group consisting of SiC, SiGe, and a compound thereof.

Here, each of the two-element compound, the three-element compound, or the four-element compound may be present in a particle in a uniform concentration or may be present in the same particle in a partially different concentration. Also, a quantum dot structure may have a core/shell structure in which one quantum dot surrounds another quantum dot. An interface between the core and the shell may have a concentration gradient in which the concentration of an element of the shell decreases toward the center of the shell.

According to some embodiments, a quantum dot may have a core-shell structure including the core and the shell surrounding the core as described above. The shell of the quantum dot may function as a protective layer for preventing chemical degeneration of the core and maintaining the semiconductor property and/or a charging layer for giving the quantum dots the electrophoretic property. The shell may include a single layer or multiple layers. An interface between the core and the shell may have a concentration gradient in which the concentration of an element of the shell decreases toward the center of the shell. Examples of the shell of the quantum dot may include metal or nonmetal oxide, a semiconductor compound, or a combination thereof.

For example, the metal or nonmetal oxide may include, for example, a two-element compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, or a three-element compound such as MgAl₂O₄, CoFe₂O₄, NiFe₂O₄, or CoMn₂O₄. However, the disclosure is not limited thereto.

Also, the semiconductor compound may include, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AIP, AlSb, etc. However, the disclosure is not limited thereto.

According to an embodiment, the quantum dot may have a full width of half maximum (FWHM) of an emission wavelength spectrum that is about 45 nm or less, preferably, about 40 nm or less, and more preferably, about 30 nm or less. Also, in this range, the degree of color purity or color reproduction may be improved. Also, the light emitted through this quantum dot may be emitted in all directions, and thus, a light viewing angle may be improved.

Also, a shape of the quantum dot corresponds to a shape that is well-known in the art and is not particularly limited. However, in more detail, the quantum dot may have a spherical shape, a pyramid shape, a multi-arm shape, a cubic nano-particle shape, a nano-tube shape, a nano-wire shape, a nano-fiber shape, a nano-plate particle shape, etc.

The quantum dot may adjust a color of light that is emitted according to the particle size and, thus, the quantum dot may have various emission colors such as blue, red, green, etc.

The first scattering particle SC1, the second scattering particle SC2, and the third scattering particle SC3 may scatter light so that a greater amount of light may be emitted. The first scattering particle SC1, the second scattering particle SC2, and the third scattering particle SC3 may increase the light-emission efficiency. At least one of the first scattering particle SC1, the second scattering particle SC2, and the third scattering particle SC3 may include any one of metal and metal oxide to evenly scatter the light. For example, at least one of the first scattering particle SC1, the second scattering particle SC2, and the third scattering particle SC3 may include at least one of TiO₂, ZrO₂, Al₂O₃, In₂O₃, ZnO, SnO₂, Sb₂O₃, and ITO. Also, at least one of the first scattering particle SC1, the second scattering particle SC2, and the third scattering particle SC3 may have the refractive index of 1.5 or greater. Thus, the light-emission efficiency of the functional layer FNL may be improved. According to some embodiments, at least one of the first scattering particle SC1, the second scattering particle SC2, and the third scattering particle SC3 may be omitted.

The first photosensitive polymer BR1, the second photosensitive polymer BR2, and the third photosensitive polymer BR3 may include a transmissive organic material. For example, at least one of the first photosensitive polymer BR1, the second photosensitive polymer BR2, and the third photosensitive polymer BR3 may include polymer resins such as acryl, BCB, or HMDSO.

The second encapsulation layer TFE2 may be disposed on the second bank layer 600 and the functional layer FNL. The second encapsulation layer TFE2 may prevent or minimize damage or contamination of the functional layer FNL due to the penetration of external impurities such as moisture and/or air into the functional layer FNL and may prevent the occurrence and distribution of cracks due to an external force. The second encapsulation layer TFE2 may enhance the protection of the functional layer FNL in the display apparatus 1 that does not include an upper substrate and has a structure in which the components are stacked on the single substrate 100. Thus, the reliability of the display apparatus 1 may be improved.

The second encapsulation layer TFE2 may cover the display area DA and may extend to the outside of the display area DA, for example, to the non-display area NDA. The second encapsulation layer TFE2 may include at least one organic encapsulation layer and at least one inorganic encapsulation layer. For example, the second encapsulation layer TFE2 may include a third inorganic encapsulation layer 710, a second organic encapsulation layer 720, and a fourth inorganic encapsulation layer 730 that are sequentially stacked.

The third inorganic encapsulation layer 710 and the fourth inorganic encapsulation layer 730 may include at least one inorganic material from among aluminum oxide, titanium oxide, tantalum oxide, hafnium oxide, ZnO, SiOₓ, SiNₓ, and SiON. The second organic encapsulation layer 720 may include a polymer-based material. The polymer-based material may include acryl-based resins, epoxy-based resins, polyimide, polyethylene, etc. According to an embodiment, the second organic encapsulation layer 720 may include acrylate. The second organic encapsulation layer 720 may be formed by curing a monomer or by being coated with a polymer.

The color filter CFL may be disposed above the second encapsulation layer TFE2. According to an embodiment, the color filter CFL may be directly formed on an upper surface (a z-axis direction) of the second encapsulation layer TFE2 and may include the first color filter 810, the second color filter 820, and the third color filter 830. The first color filter 810 may be disposed above the first quantum-dot layer 510 to correspond to the first sub-pixel PX1, the second color filter 820 may be disposed above the second quantum-dot layer 520 to correspond to the second sub-pixel PX2, and the third color filter 830 may be disposed above the transmission layer 530 to correspond to the third sub-pixel PX3. The first to third color filters 810 to 830 may include photosensitive resins. Also, each of the first to third color filters 810 to 830 may include a pigment or a dye representing a unique color.

The first color filter 810 may include a red color filter. For example, the first color filter 810 may transmit only light of the wavelength of about 630 nm to about 780 nm. The first color filter 810 may include a red pigment or dye. The second color filter 820 may include a green color filter. For example, the second color filter 820 may transmit only light of the wavelength of about 495 nm to about 570 nm. The second color filter 820 may include a green pigment or dye. The third color filter 830 may include a blue color filter. For example, the third color filter 830 may transmit only light of the wavelength of about 450 nm to about 495 nm. The third color filter 830 may include a blue pigment or dye.

The color filter CFL may reduce reflection of external light incident into the display apparatus 1. For example, when the external light reaches the first color filter 810, only light of the predetermined wavelength as described above may pass through the first color filter 810, and light of other wavelengths may be absorbed by the first color filter 810. Thus, only the light of the predetermined wavelength from the external light incident into the display apparatus 1 may pass through the first color filter 810, and some of the transmitted light may be reflected from the opposite electrode 230 and/or the first sub-pixel electrode 210R disposed therebelow and emitted to the outside again. The first color filter 810 may allow only some of the external light incident into the display apparatus 1, for example, the external light incident into where the first sub-pixel PX1 is located to be reflected to the outside and may thus reduce the reflection of external light. This aspect may be applied to the second color filter 820 and the third color filter 830 as well.

At least two selected from the first color filter 810, the second color filter 820, and the third color filter 830 may overlap each other in the non-emission area. With regard to this aspect, FIG. 5 illustrates that a portion of each of the first color filter 810, the second color filter 820, and the third color filter 830 may overlap one another in the non-emission area. At least a portion of each of the first to third color filters 810 to 830 may overlap one another to define a light-blocking portion BP. Thus, the color filter CFL may prevent or reduce the mixture of colors even when there is no additional light-blocking member like a black matrix.

In other words, a portion in which the first color filter 810 and the second color filter 820 overlap each other, a portion in which the second color filter 820 and the third color filter 830 overlap each other, and a portion in which the first color filter 810 and the third color filter 830 overlap each other may function as black matrices. For example, that is because there may be theoretically no light which may pass through both the first color filter 810 and the third color filter 830 at the portion in which the first color filter 810 and the third color filter 830 overlap each other, when the first color filter 810 transmits only the light of the wavelength of about 630 nm to about 780 nm and the third color filter 830 transmits only the light of the wavelength of about 450 nm to about 495 nm.

The light-blocking portion BP may overlap the partitions wall arranged between the openings of the second bank layer 600, for example, the partition wall arranged between the first opening COP1 and the second opening COP2, the partition wall arranged between the second opening COP2 and the third opening COP3, and the partition wall arranged between the first opening COP1 and the third opening COP3.

The overcoat layer 900 may be disposed to cover the color filter CFL. The overcoat layer 900 may include an organic layer including an organic material. For example, the overcoat layer 900 may include a colorless transmissive organic material such as acryl-based resins. The overcoat layer 900 may protect the color filter CFL and may planarize an upper surface of the color filter CFL. A lower surface of the overcoat layer 900 may have a concavo-convex structure due to a stack structure of the first to third color filters 810 to 830 of the color filter CFL. An upper surface of the overcoat layer 900 may be flat. According to an embodiment, a capping layer CL may be disposed above the overcoat layer 900. The capping layer CL may cover not only the display area DA, but may also cover the outside of the display area DA, for example, by extending to the non-display area NDA. Also, according to some embodiments, another layer such as a capping layer, etc., may also be disposed between the overcoat layer 900 and the color filter CFL. The capping layer CL may include an inorganic material. According to some embodiments, the overcoat layer 900 may be covered by a window (not shown).

The non-display area NDA may be an area which may not provide an image and may at least partially surround the display area DA. According to an embodiment, the non-display area NDA may entirely surround the display area DA. A driver or a main voltage line configured to provide electrical signals or a power supply to pixel circuits may be arranged in the non-display area NDA. The non-display area NDA may include the pad PAD which is an area to which an electrical device or a printed circuit board may be electrically connected.

The first buffer layer 111, the second buffer layer 112, and the gate insulating layer 113 may be sequentially stacked on the substrate 100 in the non-display area NDA. As described above, the first buffer layer 111 and the second buffer layer 112 may include an inorganic insulating material such as SiNₓ, SiON, and SiOₓ, and may include a single layer or multiple layers including the inorganic insulating materials described above.

The interlayer insulating layer 115 may be disposed on the gate insulating layer 113. The interlayer insulating layer 115 may include an inorganic insulating material such as SiOₓ, SiNₓ, SiON, aluminum oxide, titanium oxide, tantalum oxide, hafnium oxide, or zinc oxide.

A plurality of dam portions DM may be disposed on the interlayer insulating layer 115. That is, the display apparatus 1 may further include the plurality of dam portions DM arranged in the non-display area NDA. For example, the display apparatus 1 may include a first dam portion DM1, a second dam portion DM2, and a third dam portion DM3. The first dam portion DM1, the second dam portion DM2, and the third dam portion DM3 may be arranged to be sequentially adjacent to the display area DA. The first to third dam portions DM1 to DM3 may be spaced apart from each other. For example, the second dam portion DM2 may be spaced apart from the first dam portion DM1 in an external direction, and the third dam portion DM3 may be spaced apart from the second dam portion DM2 in the external direction. Here, the external direction may be defined as a direction away from the display area DA of the display apparatus 1 (for example, a-x direction of FIG. 5).

According to an embodiment, each of the plurality of dam portions DM may entirely surround the display area DA in a plan view. For example, the first dam portion DM1, the second dam portion DM2, and the third dam portion DM3 may have a closed loop shape surrounding the display area DA in the plan view.

Also, each of the first to third dam portions DM1 to DM3 may have a stack structure including a plurality of layers. For example, the first dam portion DM1 may include a first layer DM11 and a second layer DM12 on the first layer DM11, the second dam portion DM2 may include a first layer DM21 and a second layer DM22 on the first layer DM21, and the third dam portion DM3 may include a first layer DM31 and a second layer DM32 on the first layer DM31. According to an embodiment, the first layers DM11, DM21, and DM31 may include the same material and may be arranged on the same layer as the planarization layer 118. For example, the first layers DM11 to DM31 may be disposed on the interlayer insulating layer 115. According to an embodiment, the second layers DM12 to DM32 may include the same material as the first bank layer 215.

The first dam portion DM1 and the second dam portion DM2 may control an area for forming the first organic encapsulation layer 320 when the first organic encapsulation layer 320 of the first encapsulation layer TFE1 is formed. For example, while an organic material in the form of a liquid forming the first organic encapsulation layer 320 is formed mainly on the display area DA, the organic material may flow in the external direction (for example, the −x direction of FIG. 5) toward the non-display area NDA from the display area DA. The first dam portion DM1 may function to primarily interrupt this flow of the organic material. When a portion of the organic material overflows the first dam portion DM1, the second dam portion DM2 may function to secondarily interrupt the flow of the overflowing organic material. Accordingly, an edge of the first organic encapsulation layer 320 may be positioned at an inner side of the first dam portion DM1 or may be positioned between the first dam portion DM1 and the second dam portion DM2 as illustrated in FIG. 5. As a result, the edge of the first organic encapsulation layer 320 may not be positioned at an outer side of the second dam portion DM2. As described above, the first dam portion DM1 and the second dam portion DM2 may control the area for forming the first organic encapsulation layer 320 such that the first organic encapsulation layer 320 is not in contact with or close to an edge or a side surface of the substrate 100.

The third dam portion DM3 may control an area for forming the overcoat layer 900 when the overcoat layer 900 is formed. For example, while an organic material in the form of a liquid forming the overcoat layer 900 is formed mainly on the display area DA, the organic material may flow in the external direction (for example, the −x direction of FIG. 5) toward the non-display area NDA. The third dam portion DM3 may function to interrupt this flow of the organic material. Also, although not shown, overflowing of the second organic encapsulation layer 720 of the second encapsulation layer TFE2 may be prevented by the second bank layer 600. Overflowing of the second organic encapsulation layer 720 of the second encapsulation layer TFE2 may be prevented by the third dam portion DM3.

The pad PAD may be arranged between the third dam portion DM3 and an edge dam portion HD to be described below. The first inorganic encapsulation layer 310, the second inorganic encapsulation layer 330, and the capping layer CL may include holes to expose the interlayer insulating layer 115 according to an embodiment. The pad PAD may be disposed on the interlayer insulating layer 115 exposed by the first inorganic encapsulation layer 310, the second inorganic encapsulation layer 330, and the capping layer CL. According to an embodiment, the pad PAD may include a first conductive layer PAD1 and a second conductive layer PAD2 disposed on the first conductive layer PAD1. The first conductive layer PAD1 may be disposed on the interlayer insulating layer 115 and may be electrically connected to lines therebelow through a contact hole (not shown) passing through the interlayer insulating layer 115. According to an embodiment, the first conductive layer PAD1 may include the same material and may be disposed on the same layer as the source electrode SE and the drain electrode DE. The second conductive layer PAD2 may be electrically connected to an electrical device or a printed circuit board. According to an embodiment, the second conductive layer PAD2 may include the same material as the sub-pixel electrodes 210R, 210G, and 210B.

The edge dam portion HD may be arranged between the pad PAD and an edge of the substrate 100. In other words, the edge dam portion HD may be arranged at an external end of the non-display area NDA of the substrate 100. That is, the edge dam portion HD may be arranged at the outermost side of the substrate 100. The edge dam portion HD may be arranged at the external end of the substrate 100, that is, at the outermost side of the substrate 100, and thus, the first dam portion DM1, the second dam portion DM2, and the third dam portion DM3 may be arranged at an inner side (for example, a +x direction of FIG. 5) of the edge dam portion HD. Here, the inner side may be defined as a direction (for example, the +x direction of FIG. 5) of the display apparatus 1 from the non-display area NDA toward the display area DA.

According to an embodiment, the edge dam portion HD may extend along the external end of the substrate 100. That is, the edge dam portion HD may entirely surround the display area DA, the dam portion DM and the pad PAD in a plan view. For example, the edge dam portion HD may have a closed loop shape surrounding the display area DA, the dam portion DM, for example, the first dam portion DM1, the second dam portion DM2, and the third dam portion DM3, and the pad PAD in the plan view.

According to an embodiment, the edge dam portion HD may be disposed on the capping layer CL. Also, the edge dam portion HD may include a resin portion HD0 and a first partition wall HD1. The resin portion HD0 and the first partition wall HD1 may extend along a circumference of the substrate 100 in the plan view.

The resin portion HD0 may be disposed above the edge, that is, the external end of the substrate 100. The resin portion HD0 may protrude in a direction toward an upper portion of the substrate 100 (for example, a +z direction of FIG. 5) from the substrate 100. According to an embodiment, a first side surface of the resin portion HD0 may be in contact with the first partition wall HD1 and may be tapered such that the width W of the resin portion HD0 may increase in the protrusion direction of the resin portion HD0 (for example, the +z direction of FIG. 5). A second side surface facing the first side surface of the resin portion HD0 may be a cross-sectional surface exposed to the outside. According to an embodiment, the cross-sectional surface of the second side surface of the resin portion HD0 may be positioned on the same plane as a cross-sectional surface of the substrate 100 and may be perpendicular to a surface of the substrate 100. Accordingly, the cross-section of the resin portion HD may have a half-trapezoidal shape in which a trapezoidal shape is cut along a vertical direction as illustrated in FIG. 5.

The first partition wall HD1 may be arranged at an inner side of the resin portion HD0, that is, in a direction toward the display area DA, and may be in contact with the first side surface of the resin portion HD0.

Here, according to an embodiment, the width W of the resin portion HD0 may be from about 25 μm or greater to about 75 μm or less. The height of the first partition wall HD1 may be from about 1.5 μm or greater to about 4.5 μm or less. As described below, the edge dam portion HD as described above may be formed by forming the first partition wall HD1 and a second partition wall (not shown) space apart from the first partition wall HD1 above the substrate 100, injecting the resin portion HD0 between the first partition wall HD1 and the second partition wall, and, then, cutting the substrate 100 and the layers above the substrate 100 along the resin portion HD0 between the first partition wall HD1 and the second partition wall in a plan view.

Here, the first partition wall HD1 may include one or more organic materials selected from the group consisting of polyimide, polyamide, acryl resins, BCB, and phenol resins. Also, the resin portion HD0 may be formed by curing acid-resistant resins. That is, the resin portion HD0 may include an acid-resistant material, for example, at least one of polyethylene, poly vinyl chloride, and a photoactive compound.

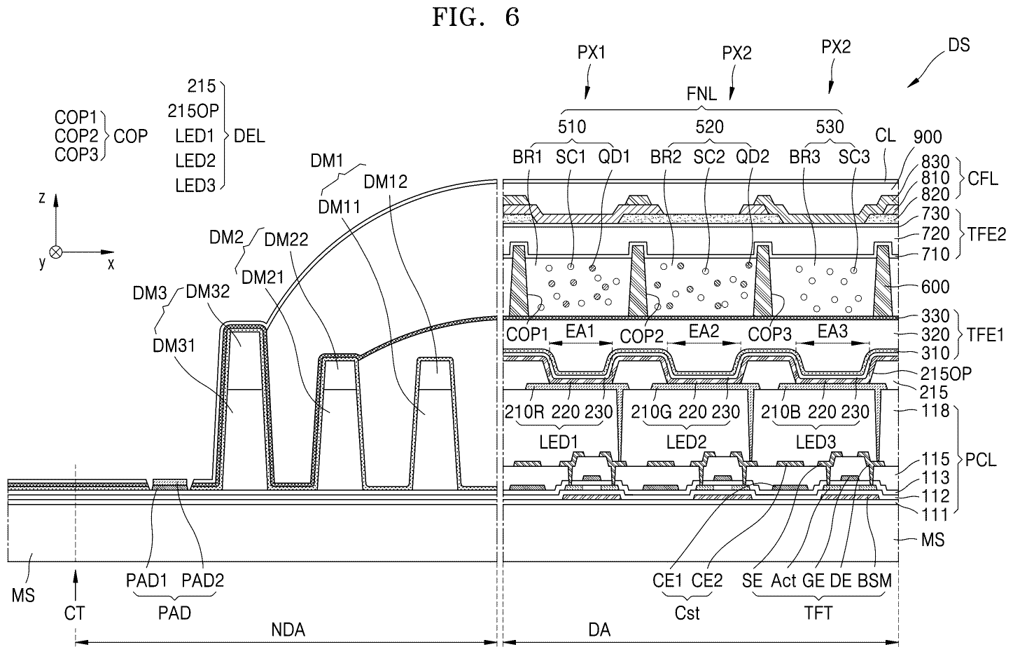

FIGS. 6 to 10 are schematic views for describing a method of manufacturing a display apparatus, according to an embodiment. The method of manufacturing the display apparatus according to an embodiment may be used to manufacture the display apparatus 1 described above but is not necessarily limited thereto.

Referring to FIG. 6, a display substrate DS may be prepared. The display substrate DS may be the display apparatus 1 in a manufacturing process. According to an embodiment, the display apparatus 1 including one or more of the circuit layer PCL, the display element layer DEL, the first encapsulation layer TFE1, the functional layer FNL, the second encapsulation layer TFE2, the color filter CFL, the overcoat layer 900, and the capping layer CL, the one or more being stacked on a mother substrate MS. As described below, the display substrate DS may be cut into cell sizes along a cutting line CT in the non-display area NDA to form the display apparatus 1. In other words, the cutting line CT may correspond to an external end of the non-display area NDA of the display apparatus 1.

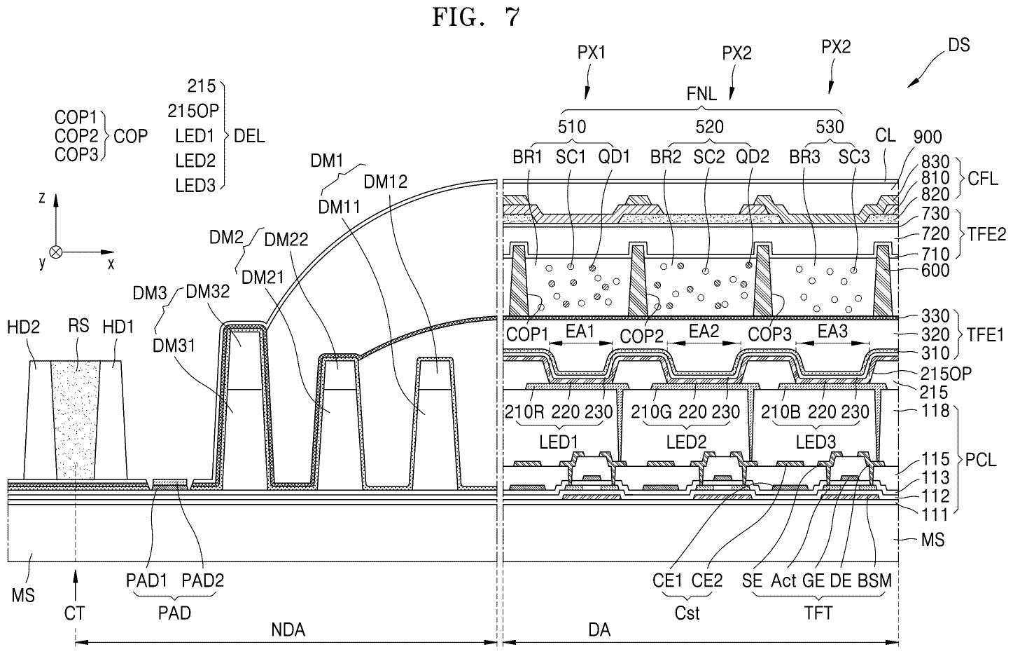

Referring to FIG. 7, a first partition wall HD1 and a second partition wall HD2 may be arranged on the display substrate DS on the capping layer CL. The first partition wall HD1 and the second partition wall HD2 may be spaced apart from each other with the cutting line CT interposed therebetween, and the first partition wall HD1 may be arranged at an inner side of the second partition wall HD2. The first partition wall HD1 may extend along an inner side of the cutting line CT and the second partition wall HD2 may extend along an outer side of the cutting line CT. Accordingly, the first partition wall HD1 and the second partition wall HD2 may extend parallel to each other to form a closed loop according to an embodiment.

After forming the first partition wall HD1 and the second partition wall HD2, a resin RS may be arranged between the first partition wall HD1 and the second partition wall HD2. In detail, the resin RS may include an acid-resistant material and may be arranged in a space between the first partition wall HD1 and the second partition wall HD2. Accordingly, the resin RS may be arranged to overlap the cutting line CT in a plan view. That is, the resin RS may be arranged above the cutting line CT and the resin RS may be formed in a closed loop shape.

Here, according to an embodiment, the resin RS may be injected using an inkjet printing process. According to an embodiment, the resin RS including an acid-resistant material may be, for example, at least one of polyethylene, poly vinyl chloride, and a photoactive compound.

Here, the first partition wall HD1 and the second partition wall HD2 may function as dams which prevents the overflowing of the resin RS. Also, the resin RS accommodated in the space between the first partition wall HD1 and the second partition wall HD2 may be cured. According to an embodiment, the resin RS may be photopolymerized.

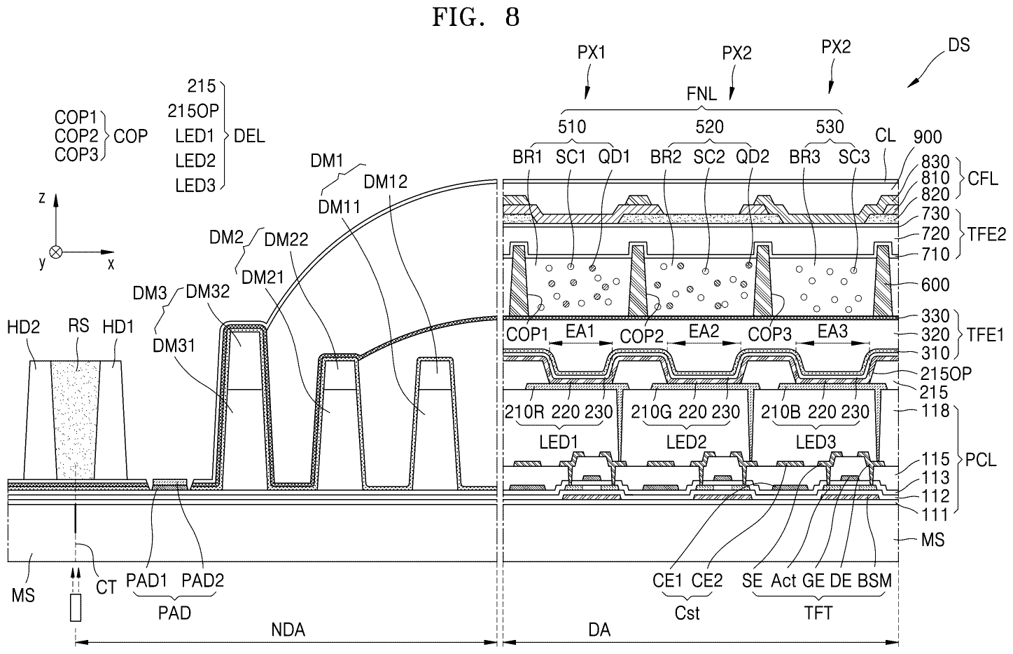

Referring to FIG. 8, according to an embodiment, the mother substrate MS may be preliminarily cut along the cutting line CT. In detail, a groove and a median crack having a predetermined depth may be formed in the mother substrate MS along the cutting line CT using a laser LASER. or the mother substrate MS may be degenerated from the upper surface of the mother substrate MS by a predetermined depth so that it may be easy to completely cut the mother substrate MS by using an etchant to be described below.

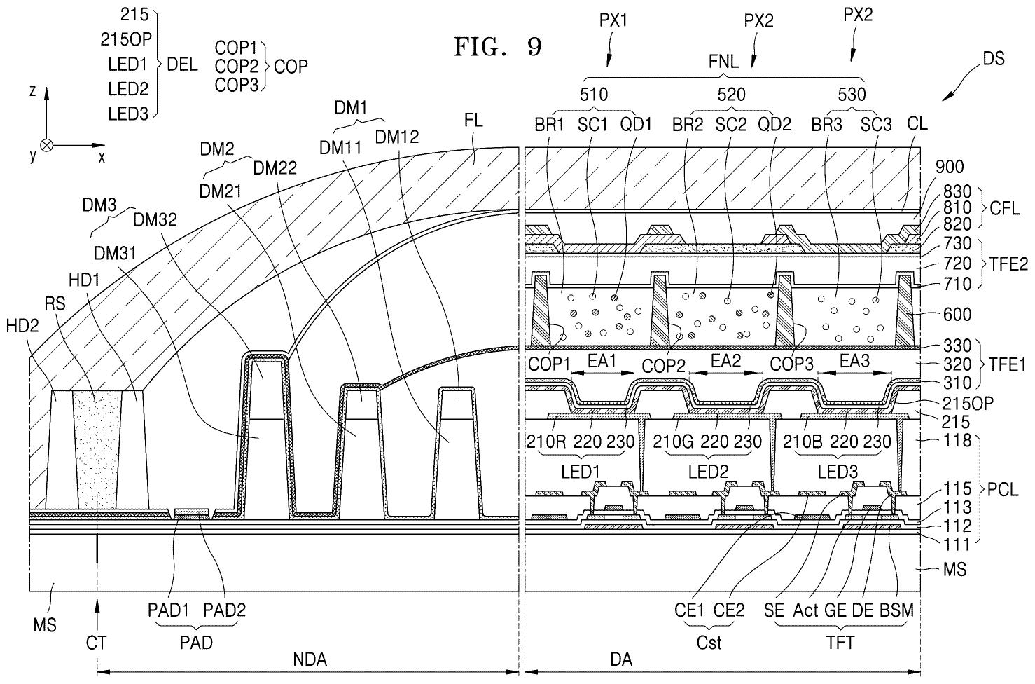

Referring to FIG. 9, a film FL may be arranged to cover the display substrate DS. In detail, the film FL may cover an uppermost layer of the display substrate DS, for example, the capping layer CL. Also, the film FL may directly contact the first partition wall HD1, the second partition wall HD2, and the resin RS to seal the display substrate DS. That is, an area at an inner side of the cutting line CT may be sealed by the film FL in a plan view. Here, according to an embodiment, the film FL may include an acid-resistant material. There may be a air gap disposed between the capping layer CL and the film FL on the dam portion DM.

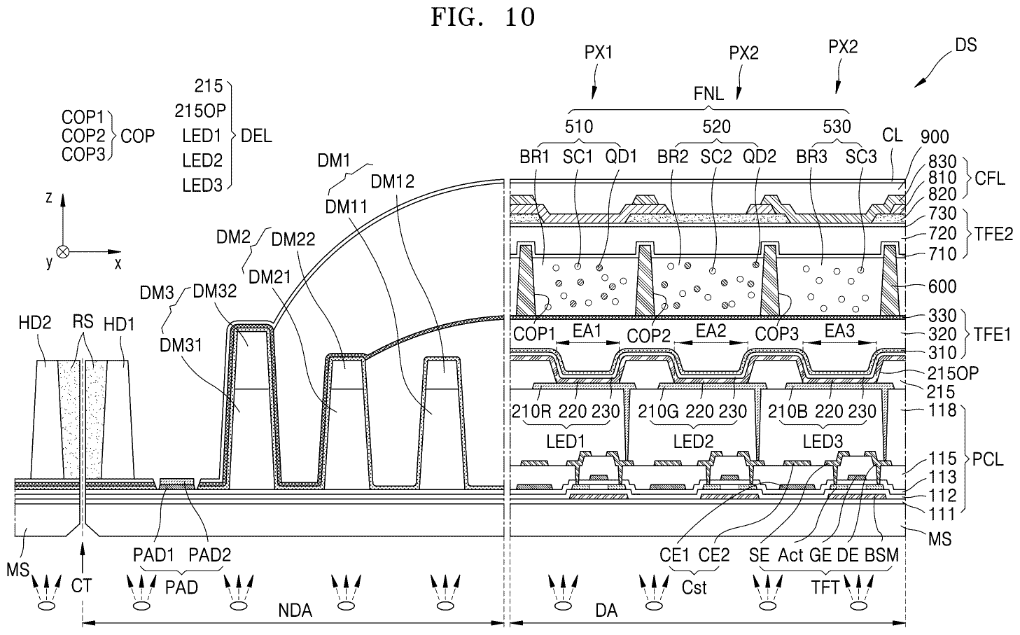

Referring to FIG. 10, the mother substrate MS may be etched. In detail, the mother substrate MS may be etched from its lower surface (for example, a surface in a-z direction of FIG. 10) by a predetermined thickness. According to an embodiment, the mother substrate MS may be etched to have the thickness of about 50 μm or greater to about 150 μm or less.

In the case of the rollable display apparatus 1, it may be necessary to reduce the thickness of the substrate in order to obtain a rolling curvature radius. Thus, in order to reduce the thickness of the mother substrate MS, the mother substrate MS may be etched by using an etchant to reduce a thickness of the mother substrate. Also, the mother substrate MS may be separated along the cutting line CT in a plan view. In detail, the mother substrate MS may be etched from its lower surface to the preliminarily cut portion, and the etchant may flow into a portion that is preliminarily cut so as to cut the mother substrate MS. Here, as the mother substrate MS is cut, cracks may occur, and thus, the plurality of layers disposed above the mother substrate MS and resins RS may also be disintegrated along the cracks.

When the display substrate DS is cut along the cutting line CT by an etchant as described above, the etchant may penetrate into a portion of the mother substrate MS that is preliminarily cut by a laser preprocessing process, and thus, layers on the mother substrate MS, for example, the pad portion PAD, etc. may be damaged. According to embodiments, the resin RS may be arranged to overlap the cutting line CT of the display substrate DS in a plan view and the resin RS may include an acid-resistant material, and thus, the penetration of an etchant into the inner side of the cutting line CT of the display substrate DS, which may cause damage to the line layers etc., may be prevented.

Also, according to an embodiment, the etchant may further chamfer an edge of the mother substrate MS. Thus, the display substrate DS may be cut into the cell sizes along the cutting line CT in the plan view and may be manufactured as the display apparatus 1. Also, the film FL may be removed after the etching is completed.

According to embodiments, when a display substrate is cut by using an etchant, the penetration of the etchant into the inner side of the display substrate to damage the lines may be prevented.

By doing so, a display apparatus having improved display quality and a method of manufacturing the display apparatus may be realized.

Effects of the one or more of the embodiments described above are not limited to the effects described above, and other effects that are not described may be clearly understood by one of ordinary skill in the art from the disclosure of the claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims.

What is claimed is:

1. A display apparatus comprising:
a substrate comprising a display area and a non-display area outside the display area;
a display element layer comprising a light-emitting diode disposed in the display area;
an encapsulation layer disposed to cover the display element layer;
a pad portion disposed in the non-display area; and an edge dam portion disposed at an outside of the pad portion in the non-display area to be apart from the display area.

2. The display apparatus of claim 1, wherein the edge dam portion is disposed along a circumference of the substrate.

3. The display apparatus of claim 1, wherein the edge dam portion protrudes in an upper direction from the outer end of the substrate.

4. The display apparatus of claim 3, wherein the edge dam portion comprises:
a resin portion disposed in the non-display area at the outer end of the substrate and protruding in the upper direction; and
a first partition wall disposed at an inner side of the resin portion toward the display area.

5. The display apparatus of claim 4, wherein the resin portion comprises an acid-resistant material.

6. The display apparatus of claim 5, wherein the acid-resistant material comprises at least one of polyethylene, poly vinyl chloride, and a photoactive compound.

7. The display apparatus of claim 4, wherein a width of the resin portion is from about 25 μm or greater to about 75 μm or less.

8. The display apparatus of claim 4, wherein a height of the first partition wall is from about 1.5 μm or greater to about 4.5 μm or less.

9. The display apparatus of claim 1, wherein a thickness of the substrate is in a range of about 50 μm or greater to about 150 μm or less.

10. The display apparatus of claim 1, further comprising a first dam disposed inside the pad portion in the non-display area,
wherein the edge dam portion is disposed at an outer side of the first dam.

11. The display apparatus of claim 10, further comprising:
an overcoat layer disposed above the encapsulation layer; and
a second dam disposed between the first dam and the pad portion in the non-display.

12. The display apparatus of claim 10, wherein the pad portion is disposed between the edge dam portion and the second dam portion.

13. A method of manufacturing a display apparatus, the method comprising:
preparing a display substrate including a mother substrate and a plurality of layers stacked on the mother substrate;
forming a first partition wall and a second partition wall at an outer side of a pad portion, the first partition wall being disposed inside of a cutting line of the display substrate and the second partition wall being disposed outside of the cutting line of the display substrate;
forming a resin in a space between the first partition wall and the second partition wall to overlap the cutting line in a plan view; and
separating the display substrate along the cutting line.

14. The method of claim 13, further comprising preliminarily cutting the mother substrate by using a laser on the mother substrate along the cutting line before the separating the display substrate.

15. The method of claim 14, wherein the separating the display substrate comprises etching the mother substrate so that a thickness of the mother substrate is reduced.

16. The method of claim 15, wherein an etchant penetrates through a portion of the mother substrate that is preliminarily cut and cuts the display substrate.

17. The method of claim 15, wherein the thickness of the mother substrate is in a range of about 50 μm or greater to about 150 μm or less.

18. The method of claim 17, wherein the resin comprises an acid-resistant material.

19. The method of claim 18, wherein the acid-resistant material comprises at least one of polyethylene, poly vinyl chloride, and a photoactive compound.

20. The method of claim 13, wherein a width of the resin is from about 50 μm or greater to about 150 μm or less.
